(19) United States
(12) Patent Application Publication
(10) Pub. No.: US 2026/0025938 A1
(43) Pub. Date: Jan. 22, 2026

(54) Server System Storage System Storage Module Attachment System

(71) Applicant: Dell Products L.P., Round Rock, TX (US)

(72) Inventors: Yen-Lin Wang, Taipei (TW); Hsin-Yi Hsieh, Changhua County (TW); Ching-Yuan Wang, New Taipei City (TW)

(21) Appl. No.: 18/777,750

(22) Filed: Jul. 19, 2024

(51) Int. Cl. H05K 7/14

(52) U.S. Cl. CPC H05K 7/1489

(57) ABSTRACT

A storage component mounting system of storage system. The storage component mounting system includes a card mounting device; and, a storage component attachment system, the storage component attachment system including a card attachment portion, the card attachment portion including a card fastener, the card fastener physically coupling the storage component to the card mounting device; a pivot portion, the pivot portion enabling the card attachment portion to pivot between a plurality of locations on the card mounting device to enable storage components corresponding to a plurality of storage component form factors to be mounted to a single card mounting device design; and, a card attachment extension portion, the card attachment extension portion extending between the card attachment portion and the pivot portion.

### BACKGROUND OF THE INVENTION

### FIELD OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a storage system with a storage component attachment system via which different length storage components can be installed into a storage module of the storage system.

In one embodiment, the invention relates to a storage component attachment system for attaching a storage component within a storage system for an information handling system, comprising: a card attachment portion, the card attachment portion including a card fastener, the card fastener physically coupling the storage component to a card mounting device; a pivot portion, the pivot portion enabling the card attachment portion to pivot between a plurality of locations on the card mounting device to enable storage components corresponding to a plurality of storage component form factors to be mounted to a single card mounting device design; and, a card attachment extension portion, the card attachment extension portion extending between the card attachment portion and the pivot portion.

In another embodiment, the invention relates to a storage component mounting system of a storage system comprising: a card mounting device; and, a storage component attachment system, the storage component attachment system comprising a card attachment portion, the card attachment portion including a card fastener, the card fastener physically coupling the storage component to the card mounting device; a pivot portion, the pivot portion enabling the card attachment portion to pivot between a plurality of locations on the card mounting device to enable storage components corresponding to a plurality of storage component form factors to be mounted to a single card mounting device design; and, a card attachment extension portion, the card attachment extension portion extending between the card attachment portion and the pivot portion.

In another embodiment, the invention relates to a system comprising: a chassis; a processor contained within the chassis; a data bus coupled to the processor; and, a storage component mounting system: a card mounting device; and, a storage component attachment system, the storage component attachment system comprising a card attachment portion, the card attachment portion including a card fastener, the card fastener physically coupling the storage component to the card mounting device; a pivot portion, the pivot portion enabling the card attachment portion to pivot between a plurality of locations on the card mounting device to enable storage components corresponding to a plurality of storage component form factors to be mounted to a single card mounting device design; and, a card attachment extension portion, the card attachment extension portion extending between the card attachment portion and the pivot portion.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a storage system with a plurality of storage cartridges.

FIG. 5 shows a perspective view of a storage cartridge of a storage system.

FIGS. 6A, 6B, 6C and 6D, generally referred to as FIG. 6, show a plurality of views of a storage component mounting system having a storage component attachment system.

FIGS. 7A, 7B, 7C and 7D, generally referred to as FIG. 7, show a plurality of views of a storage component mounting system having a storage component attachment system.

FIGS. 8A, 8B and 8C, generally referred to as FIG. 8, show a plurality of views of a storage component mounting system.

FIGS. 9A, 9B, 9C and 9D, generally referred to as FIG. 9, show a plurality of views of a storage component mounting system having a storage component attachment system.

### DETAILED DESCRIPTION

Various aspects of the disclosure include an appreciation that it is known to provide information handling systems with storage systems such as boot optimized storage systems. Various aspects of the disclosure include an appreciation that it is known to storage systems, such as boot optimized storage systems, which are hot swappable. Various aspects of the present disclosure include an appreciation that it is known to provide storage systems which can mount a plurality of storage components. Various aspects of the present disclosure include an appreciation that each of the plurality of storage components can include one or more storage devices. Various aspects of the present disclosure include an appreciation that the one or more storage devices often conform to particular storage device specifications. Various aspects of the present disclosure include an appreciation that one such storage device specification is the M.2 storage device specification. Various aspects of the present disclosure include an appreciation that storage device specifications often define particular dimensions for cards, such as internal memory cards, for the cards to conform to the storage device specification.

Various aspects of the present disclosure include an appreciation the dimensions defined by a storage device specification can include a plurality of card lengths. Various aspects of the present disclosure include an appreciation that certain storage devices can use the same connector to mate with a card edge of the card while having different lengths. For example, certain cards defined by the M.2 storage device specification form factor (e.g., the M.22280 card form factor and the M.222110 card form factor) can use the same connector to mate with a card edge of the card while having different lengths.

Various aspects of the present disclosure include an appreciation that when attaching a card to a storage system, it is known to use a card mounting device such as a card mounting printed circuit board (PCB). Various aspects of the present disclosure include an appreciation that certain card mounting devices make use of a standoff when attaching the card to card mounting device. Various aspects of the present disclosure include an appreciation that a standoff is often used to support a portion of the card opposite the card edge of the card. Various aspects of the present disclosure include an appreciation that a standoff is often used to physically attach a portion of the card to the card mounting device. Various aspects of the present disclosure include an appreciation that use of the standoff can present issues when using the same card mounting device for cards of different lengths. Accordingly, various aspects of the present disclosure include an appreciation that it would be desirable to provide a storage system with a storage component attachment system via which different length storage components can be installed into a storage module of the storage system.

A system and method for providing a storage system with a storage component attachment system via which different length storage components can be installed into a storage module of the storage system. In certain embodiments, the storage component attachment system includes a relocatable attachment component. In certain embodiments, the relocatable attachment component includes a top side relocatable attachment portion, a bottom side relocatable attachment portion, or a combination thereof. Such a storage component attachment system enables a single card mounting device design to be used for cards of different lengths. In certain embodiments, the storage attachment system supports a plurality of card form factors defined by the M.2 storage device specification (e.g., the M.22280 card form factor and the M.222110 card form factor).

Such a storage component attachment system enables a single mounting device design to support a plurality of card form factor options with an easy installation process. Such a storage component attachment system facilitates easier production build options based on a production work order. Such a storage component attachment system facilitates service or end user replacement of cards which confirm to a plurality of card form factors.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

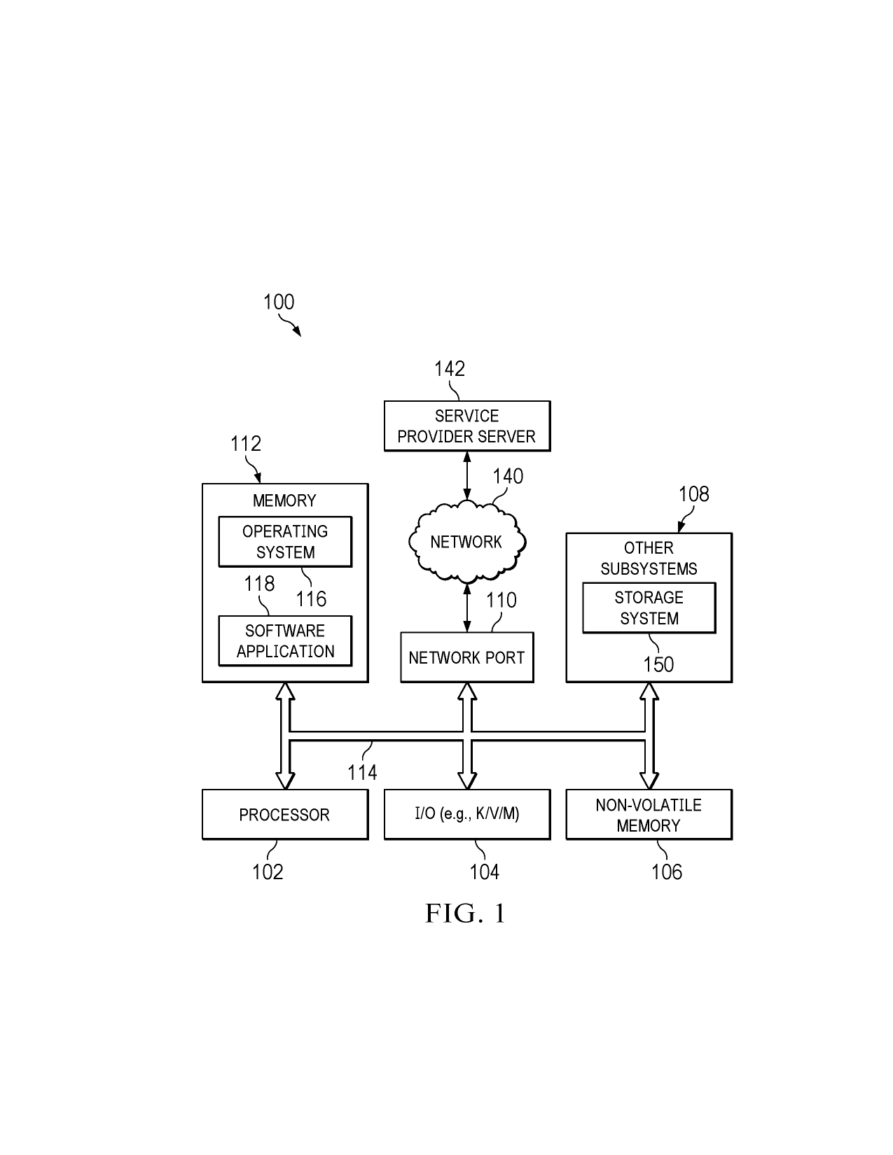

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include storage system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the storage system 150 comprises a storage component attachment system via which different length storage components can be installed into a storage module of the storage system. In certain embodiments, the storage component attachment system includes a relocatable attachment component. In certain embodiments, the relocatable attachment component includes a top side relocatable attachment portion, a bottom side relocatable attachment portion, or a combination thereof. Such a storage component attachment system enables a single card mounting device design to be used for cards of different lengths. In certain embodiments, the storage attachment system supports a plurality of card form factors defined by the M.2 storage device specification (e.g., the M.22280 card form factor and the M.222110 card form factor).

Such a storage component attachment system enables a single mounting device design to support a plurality of card form factor options with an easy installation process. Such a storage component attachment system facilitates easier production build options based on a production work order. Such a storage component attachment system facilitates service or end user replacement of cards which confirm to a plurality of card form factors.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

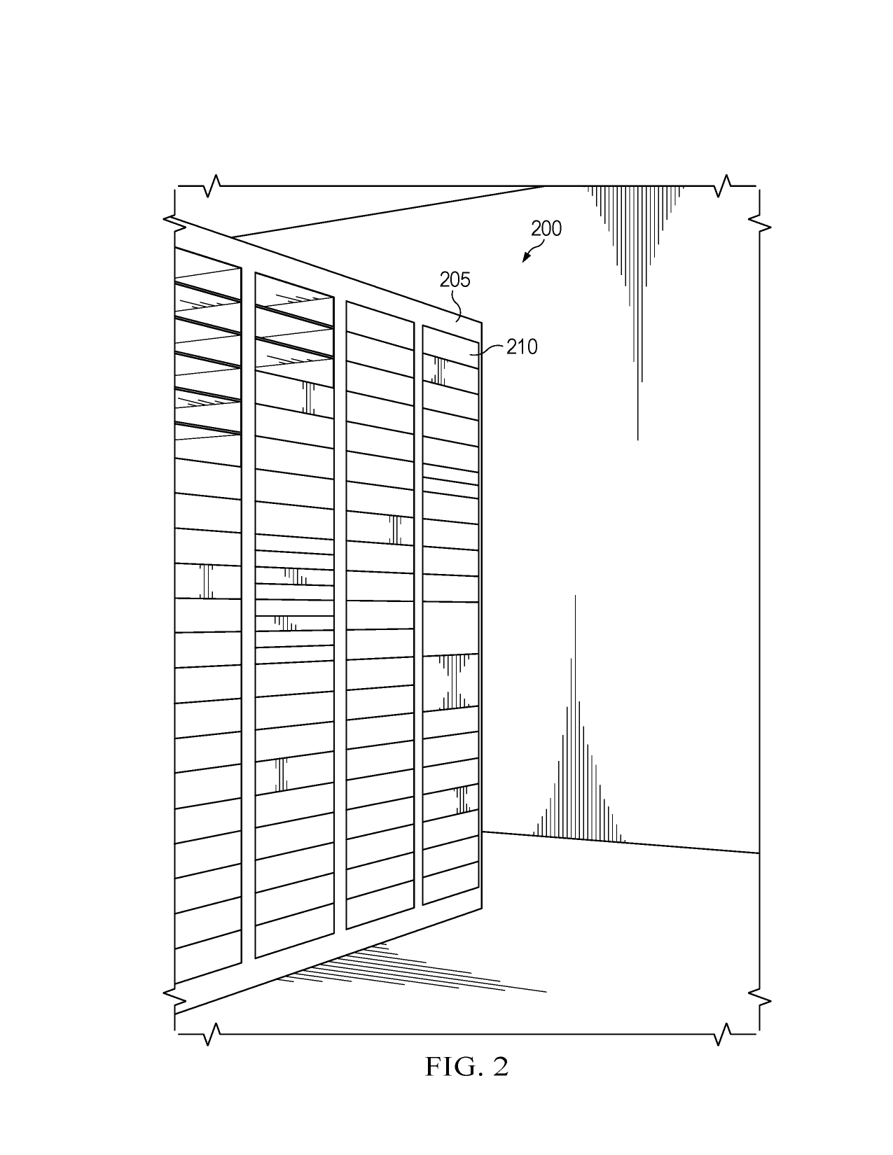

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

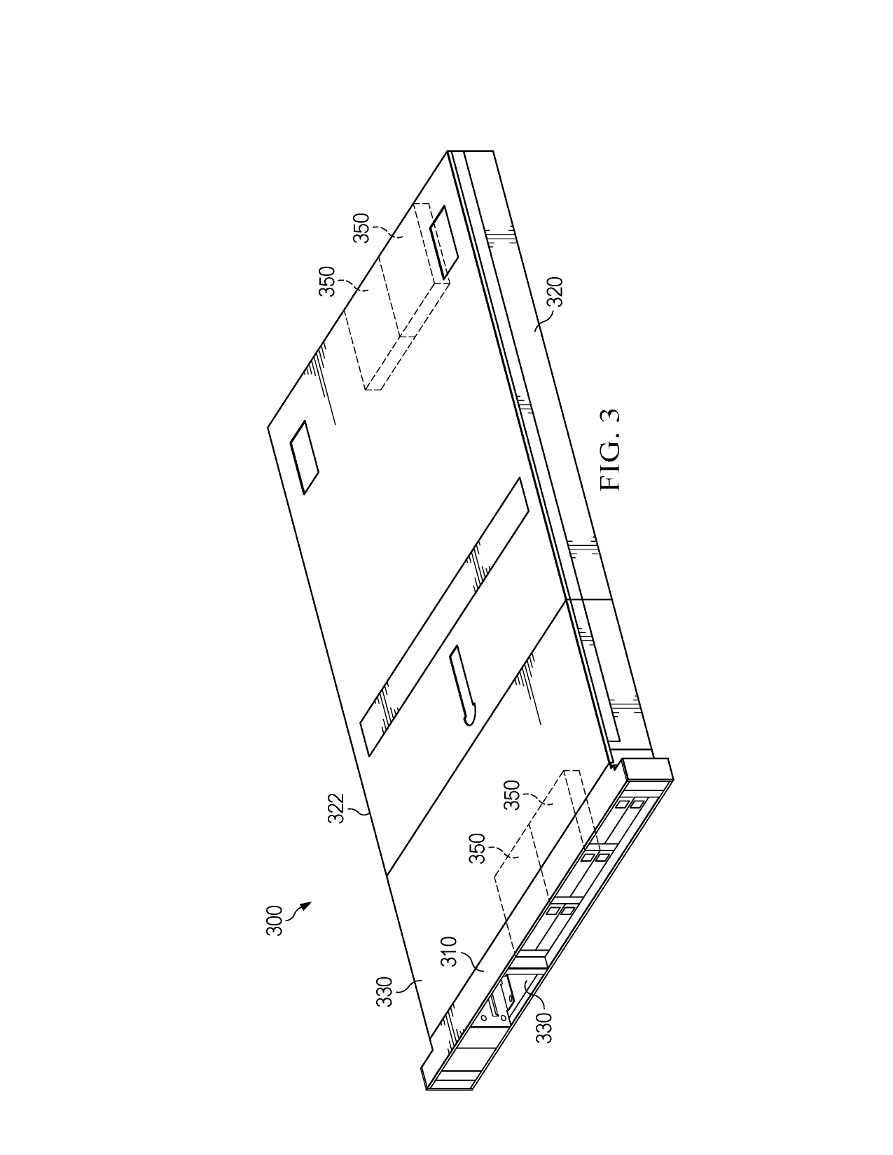

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system. In certain embodiments, components mounted in one or more of the bays 310 include a storage system 350.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card.

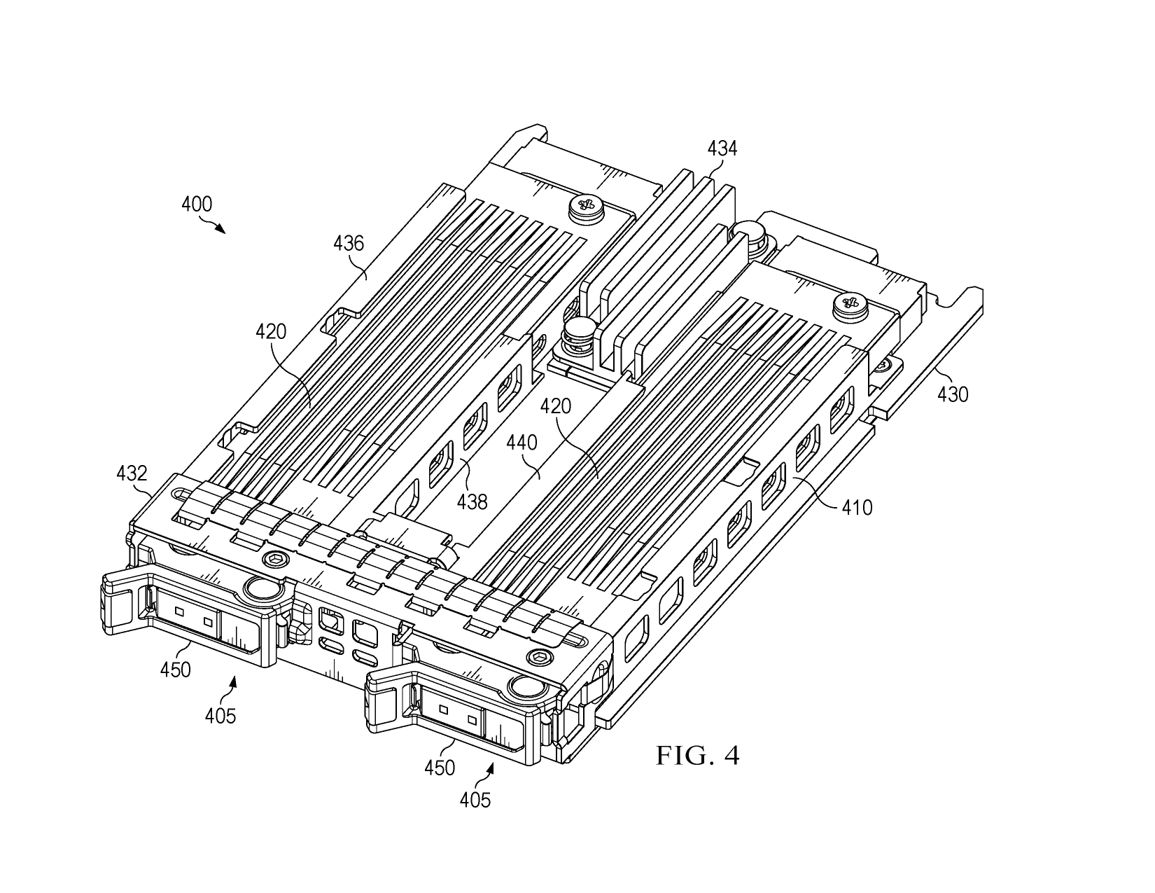

FIG. 4 shows a storage system 400 with a plurality of latching systems 405. In certain embodiments, the storage system 400 corresponds to storage system 150. In certain embodiments, each latching system 405 includes a latching mechanism and a latch engagement portion.

In certain embodiments, the storage system 400 corresponds to storage system 150. In certain embodiments, the storage module housing 410 includes a bottom wall 430, a front housing portion 432, an outside right wall 434, an outside left wall 436, an inside right wall 438, an inside left wall 440, or a combination thereof.

In certain embodiments, the housing portion 432 extends substantially perpendicularly (i.e., +/- 20%) from the bottom wall 430. In certain embodiments, the front wall extends substantially perpendicularly (i.e., +/- 20%) from the bottom wall 430. In certain embodiments, the outside right wall 434 extends substantially perpendicularly (i.e., +/- 20%) from the bottom wall 430. In certain embodiments, the outside left wall 436 extends substantially perpendicularly (i.e., +/- 20%) from the bottom wall 430. In certain embodiments, the right inside wall 438 extends substantially perpendicularly (i.e., +/- 20%) from the bottom wall 430. In certain embodiments, the left inside wall 440 extends substantially perpendicularly (i.e., +/- 20%) from the bottom wall 430. It will be appreciated that the orientations of the walls will be reversed when the storage system is installed at the rear of the information handling systems (e.g., the front housing portion 432 is effectively a rear housing portion).

In certain embodiments, the front housing portion 432 defines one or more apertures via which storage cartridge modules 420 may be installed in the storage module housing 410. In certain embodiments, pairs of left and right walls (e.g., a left outside wall and a right inside wall) include channels via which respective storage cartridges may be inserted and mounted to the storage module housing 410. In certain embodiments, the left and right walls include channels via which respective storage cartridges may be inserted and mounted to the storage module housing 410. In certain embodiments, the outside right wall 434 and the inside left wall 440 define channels via which a storage cartridge module 420 may be installed in the storage module housing 410. In certain embodiments, the outside left wall 436 and the inside right wall 438 define channels via which a storage cartridge module 420 may be installed in the storage module housing 410.

In certain embodiments, when the storage cartridge module 420 is configured in a hot swap storage media access configuration, each storage cartridge module 420 includes a respective latch 450 which allows a user to unlatch the storage cartridge module and remove the storage cartridge module from the storage system.

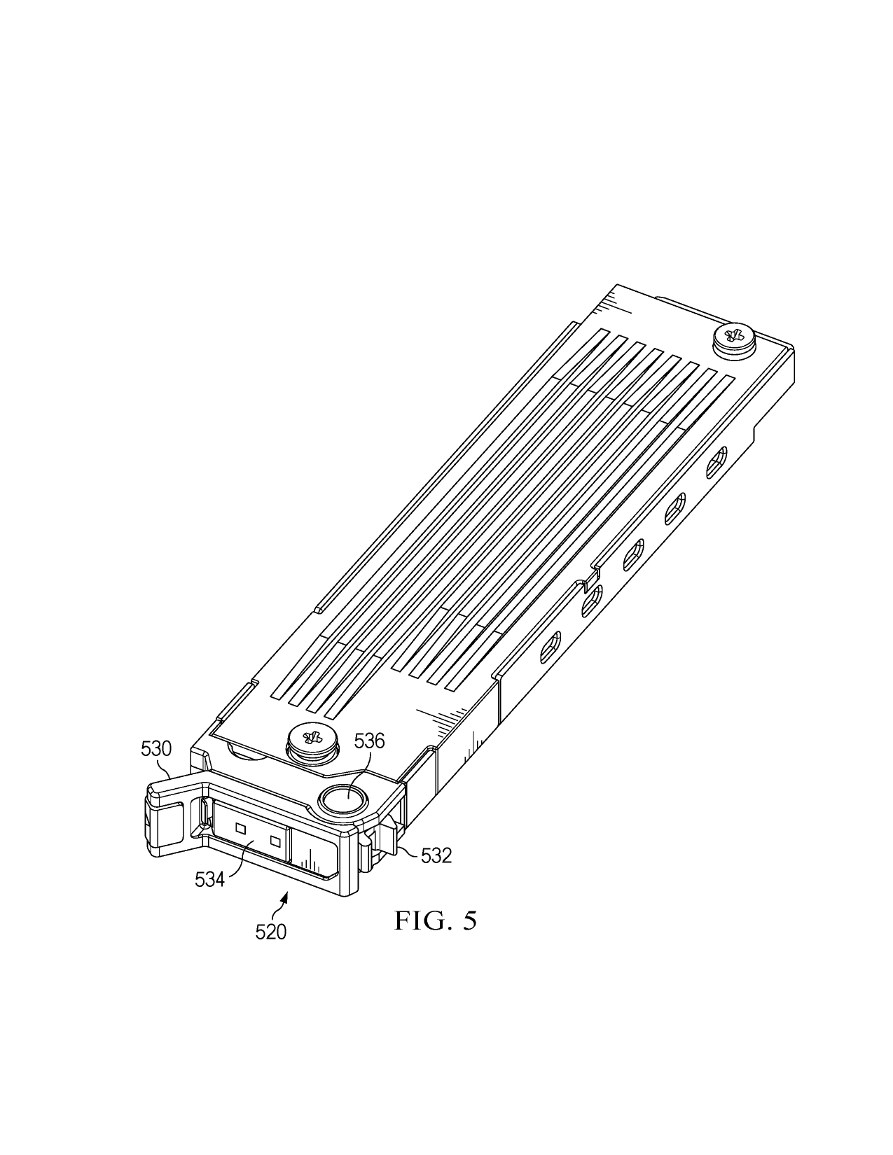

FIG. 5 shows a perspective view of a storage cartridge module 500 (also referred to as a storage module) of a storage system. In certain embodiments, the storage cartridge module 500 corresponds to storage cartridge module 420. In certain embodiments, the storage system corresponds to storage system 150.

In certain embodiments the storage cartridge module 500 includes a bottom component 510 and a top cover 512. In certain embodiments, the bottom component 510 and the top cover 512 are configured to receive a latch component 530. In certain embodiments, the bottom component 510 defines an attachment aperture, includes an attachment component, or a combination thereof. In certain embodiments, the attachment component includes a nut. In certain embodiments, the attachment aperture, the attachment component, or a combination thereof, are used to attach a latch component 530 to the storage cartridge module 500. In certain embodiments, the attachment component mates with a fastener to mount the top cover 512 to the bottom component 510.

In certain embodiments, a latch mechanism includes a latch hook portion 532. In certain embodiments, the latch 530 and the latch hook portion 532, or a combination thereof are included within a latch mechanism. In certain embodiments, the latch hook portion 532 is configured to interact with a latch engagement portion.

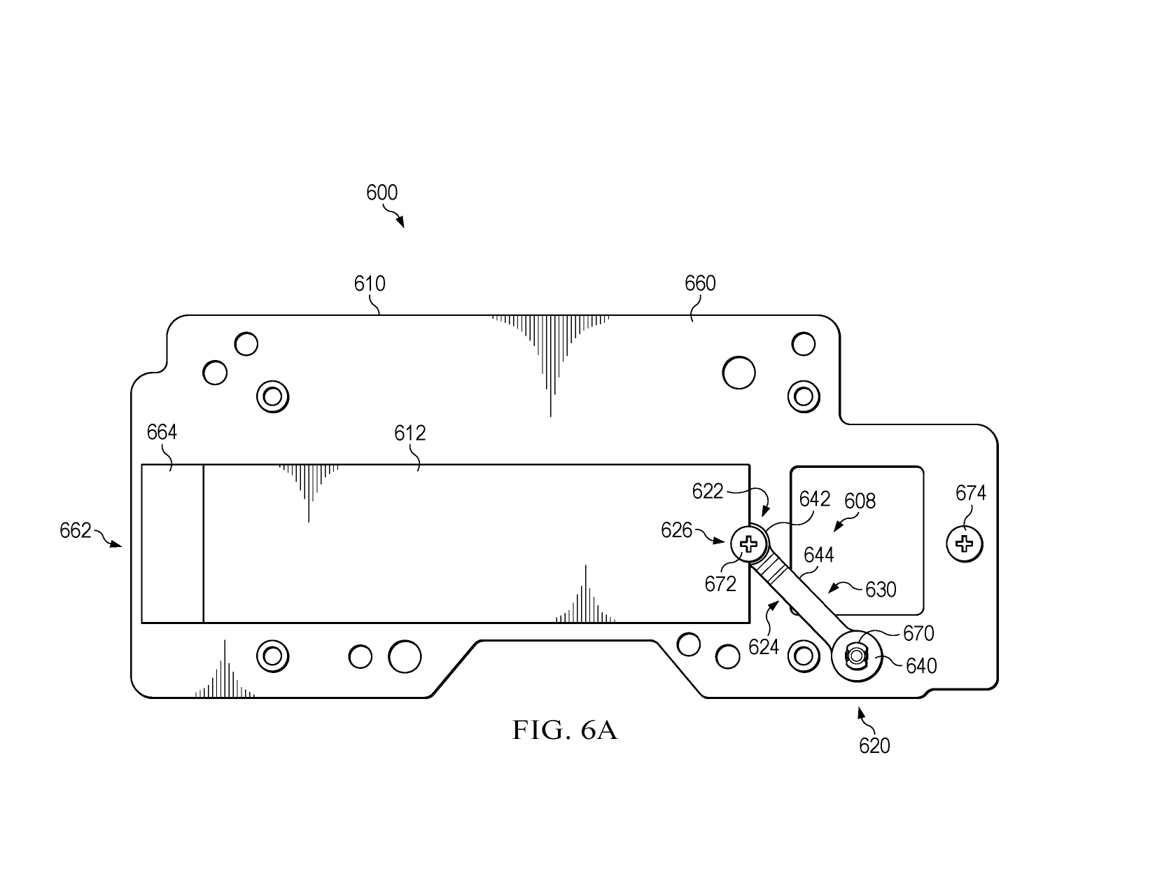

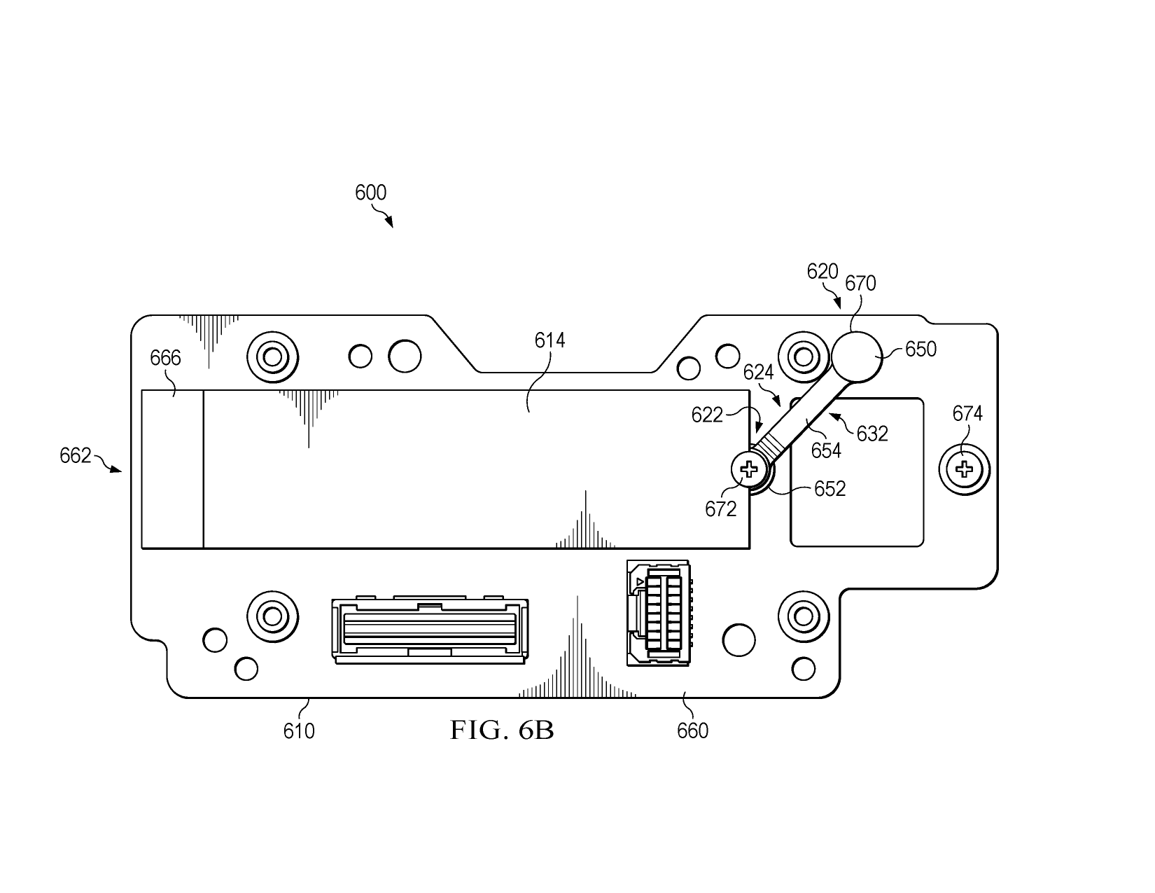

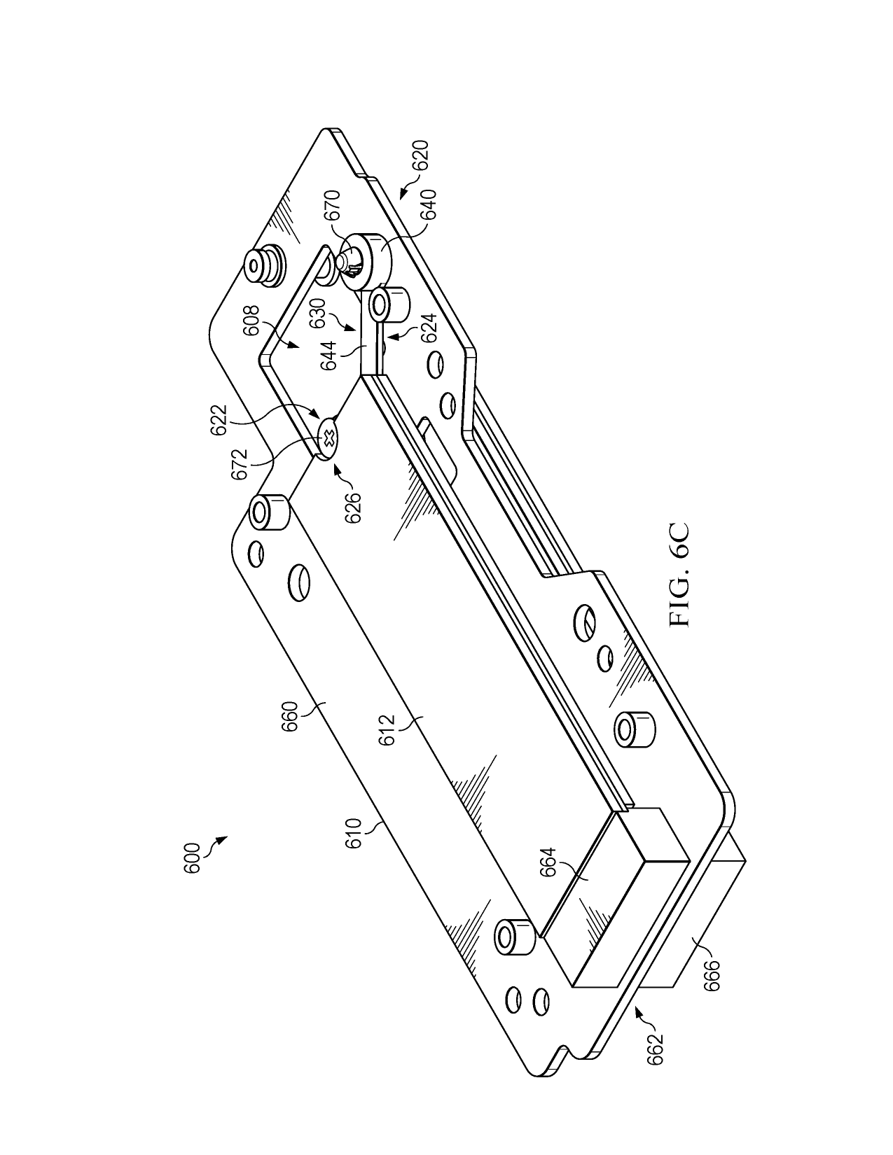

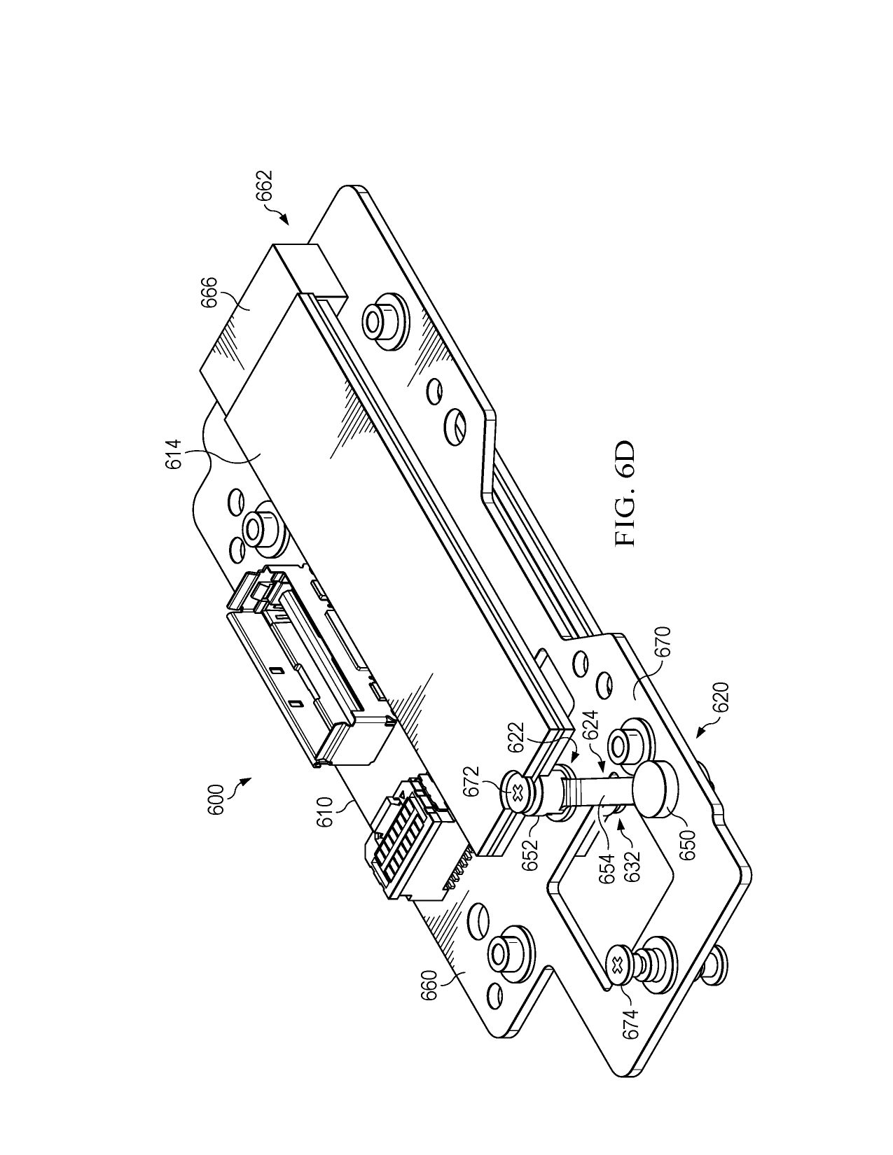

FIGS. 6A, 6B, 6C and 6D, generally referred to as FIG. 6, show a plurality of views of a storage component mounting system having a storage component attachment system. More specifically, FIG. 6A shows a top view of a storage component mounting system 600 having a storage component attachment system 605. FIG. 6B shows a bottom view of a storage component mounting system 600 having a storage component attachment system 605. FIG. 6C shows a top perspective view of a storage component mounting system 600 having a storage component attachment system 605. FIG. 6D shows a bottom perspective view of a storage component mounting system 600 having a storage component attachment system 605. In certain embodiments, the storage component mounting system 600 is included within a storage module. In certain embodiments, the storage module corresponds to storage module 500.

In certain embodiments, the storage component mounting system 600 includes the storage component attachment system 605, a card mounting device 610, a card 612, a card 614, or a combination thereof. In certain embodiments, the storage component attachment system 605 enables different length storage components to be installed into a storage module of the storage system. In certain embodiments, the storage component attachment system 605 includes a relocatable attachment component. Such a storage component attachment system 605 enables a single card mounting device design to be used for cards of different lengths. In certain embodiments, the storage attachment system supports a plurality of card form factors defined by the M.2 storage device specification (e.g., the M.22280 card form factor and the M.222110 card form factor). In certain embodiments, the card 612, the card 614, or a combination thereof, conform to the M.22280 card form factor.

In certain embodiments, the relocatable attachment component 605 includes a pivot portion 620, a card attachment portion 622, a card attachment extension portion 624, or a combination thereof. In certain embodiment, the card attachment extension portion 624 extends between the pivot portion 620 and the card attachment portion 622. In certain embodiments, the card attachment portion 622 includes a card fastener 626. In certain embodiments, card fastener 626 physically couples the card attachment portion 622 to the card mounting device 610. In certain embodiments, the card fastener 626 physically couples one edge of a card 612, 614 to the card mounting device 610.

In certain embodiments, the relocatable attachment component 605 includes a top side relocatable attachment portion 630, a bottom side relocatable attachment portion 632, or a combination thereof. In certain embodiments, the top side relocatable attachment portion 630 includes a top side pivot portion 640, a top side card attachment portion 642, a top side card attachment extension portion 644, or a combination thereof. In certain embodiment, the top side card attachment extension portion 644 extends between the top side pivot portion 640 and the top side card attachment portion 642. In certain embodiments, the top side card attachment portion 642 includes a top side card fastener 646. In certain embodiments, top side card fastener 646 physically couples the top side card attachment portion 642 to the card mounting device 610. In certain embodiments, the top side card fastener 646 physically couples one edge of a card 612 to a top side of the card mounting device 610. In certain embodiments, the edge of the card 612 is located laterally opposite to top edge card edge connector of the card 612. In certain embodiments, the top side pivot portion 640 defines a top side mounting aperture 648.

In certain embodiments, the bottom side relocatable attachment portion 632 includes a bottom side pivot portion 650, a bottom side card attachment portion 652, a bottom side card attachment extension portion 654, or a combination thereof. In certain embodiment, the bottom side card attachment extension portion 654 extends between the bottom side pivot portion 650 and the bottom side card attachment portion 652. In certain embodiments, the bottom side card attachment portion 652 includes a bottom side card fastener 656. In certain embodiments, bottom side card fastener 656 physically couples the bottom side card attachment portion 652 to the card mounting device 610. In certain embodiments, the bottom side card fastener 656 physically couples one edge of a card 614 to a bottom side of the card mounting device 610. In certain embodiments, the edge of the card 614 is located laterally opposite to the bottom side card edge connector of the card 614. In certain embodiments, the bottom side pivot portion 650 includes a bottom side mounting projection 658. In certain embodiments, the bottom side mounting projection 658 mates with the top side mounting aperture 648 to pivotally attach the top side relocatable attachment portion 630 and the bottom side relocatable attachment portion 632. In certain embodiments, the bottom side mounting projection 658 mates with the top side mounting aperture 648 to pivotally attach the top side relocatable attachment portion 630 and the bottom side relocatable attachment portion 632 such that the top side relocatable attachment portion 630 and the bottom side relocatable attachment portion 632 can pivot independent of each other.

In certain embodiments, the card mounting device 610 includes a mounting card 660, a mounting connector portion 662, or a combination thereof. In certain embodiments, the mounting card includes a mounting card printed circuit board. In certain embodiments, the mounting card includes a top portion, a bottom portion, or a combination thereof. In certain embodiments, the top portion includes a top mounting connector 664. In certain embodiments, the bottom portion includes a bottom mounting connector 666. In certain embodiments, the card 612 is electrically and physically coupled with the top mounting connector 664. In certain embodiments, the card 614 is electrically and physically coupled with the bottom mounting connector 666.

In certain embodiments, the mounting card 660 defines a relocatable attachment component pivot aperture 670, a first relocatable attachment component attachment aperture 672, a second relocatable attachment component attachment aperture 674, or a combination thereof. In certain embodiments, the relocatable attachment component pivot aperture 670 is located close to a side edge of the mounting card 660. In certain embodiments, the relocatable attachment component pivot aperture 670 is located such that the pivot portion of the relocatable attachment component does not interfere with installation of a card 612, 614. In certain embodiments, the bottom side mounting projection 658 fits through the relocatable attachment component pivot aperture 670 to pivotally attach the top side relocatable attachment portion 630 and the bottom side relocatable attachment portion 632.

In certain embodiments, the first relocatable attachment component attachment aperture 672 is located to enable the relocatable attachment component 605 to be configured in a first card attachment configuration. In certain embodiments, the first card attachment configuration enables attachment of a card conforming to a M.22280 card form factor. In certain embodiments, the second relocatable attachment component attachment aperture 674 is located to enable the relocatable attachment component 605 to be configured in a second card attachment configuration. In certain embodiments, the first card attachment configuration enables attachment of a card conforming to a M.222110 card form factor.

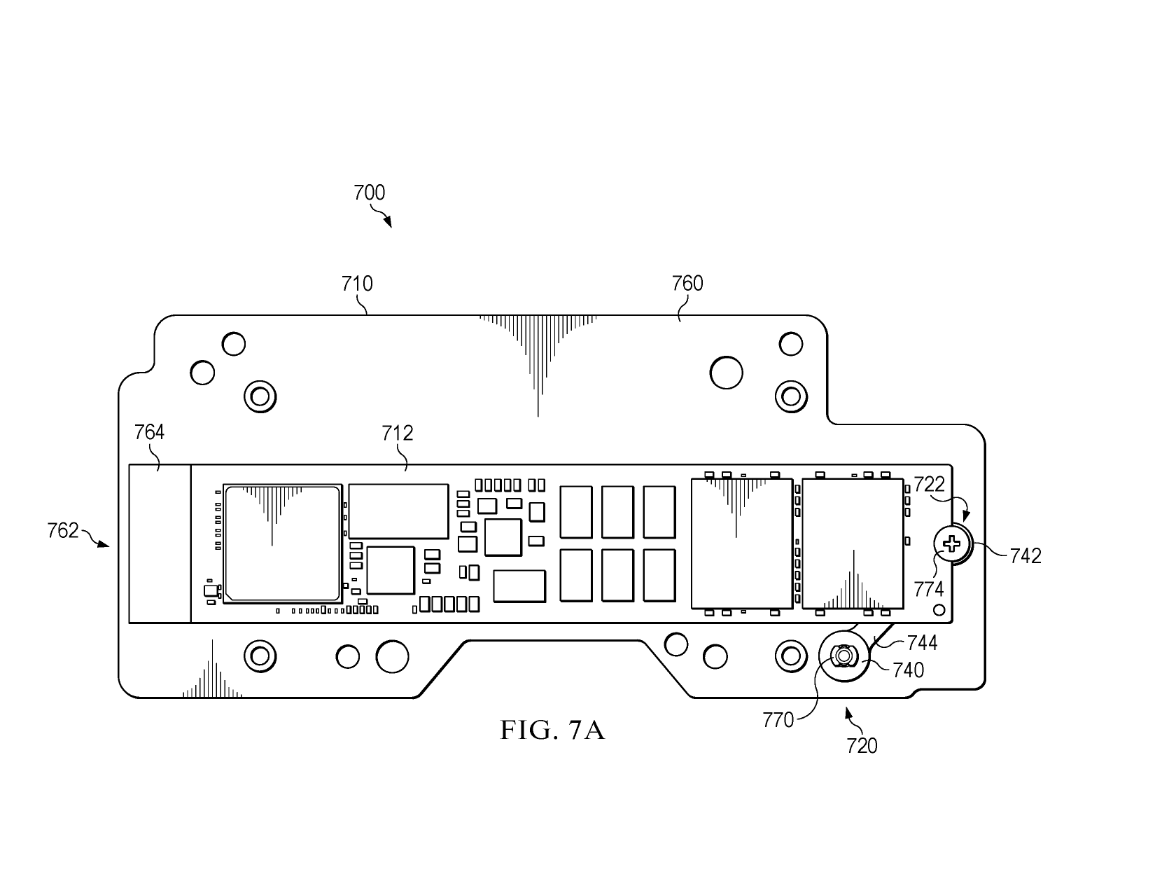

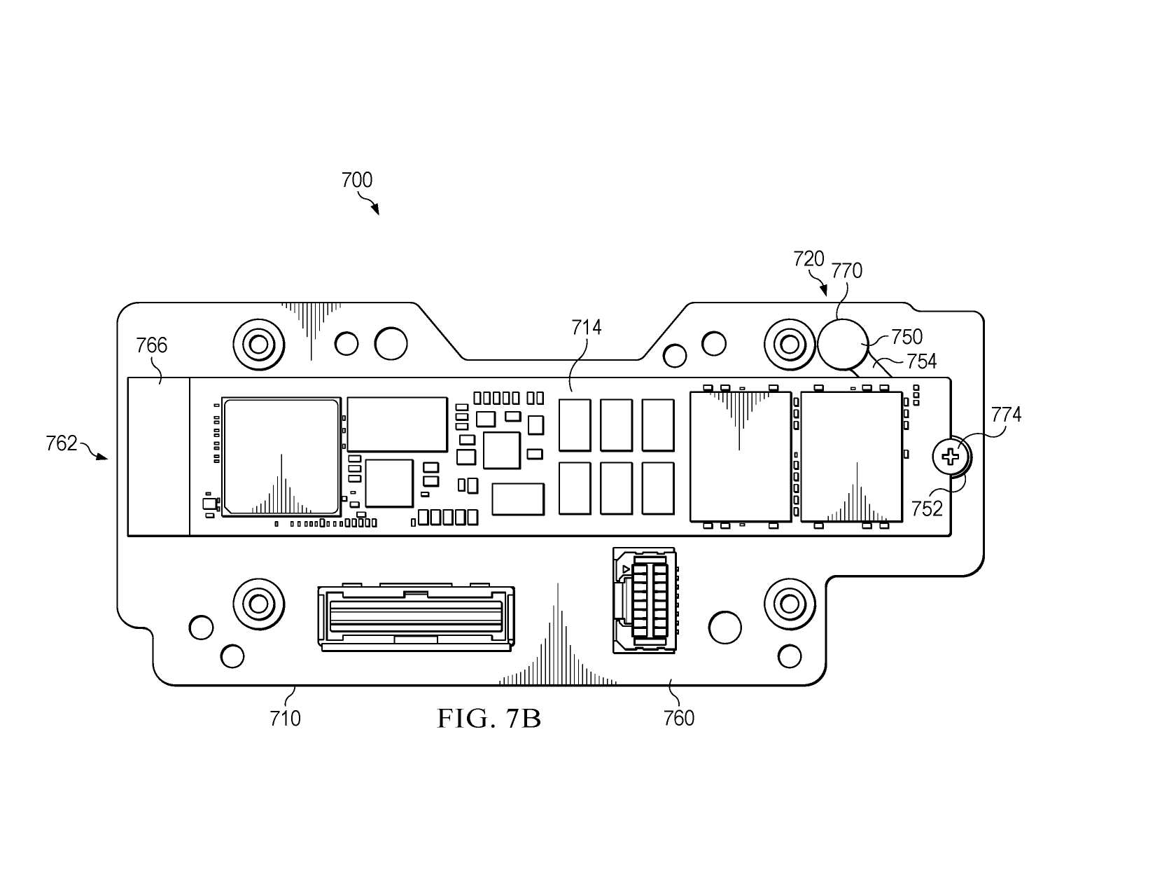

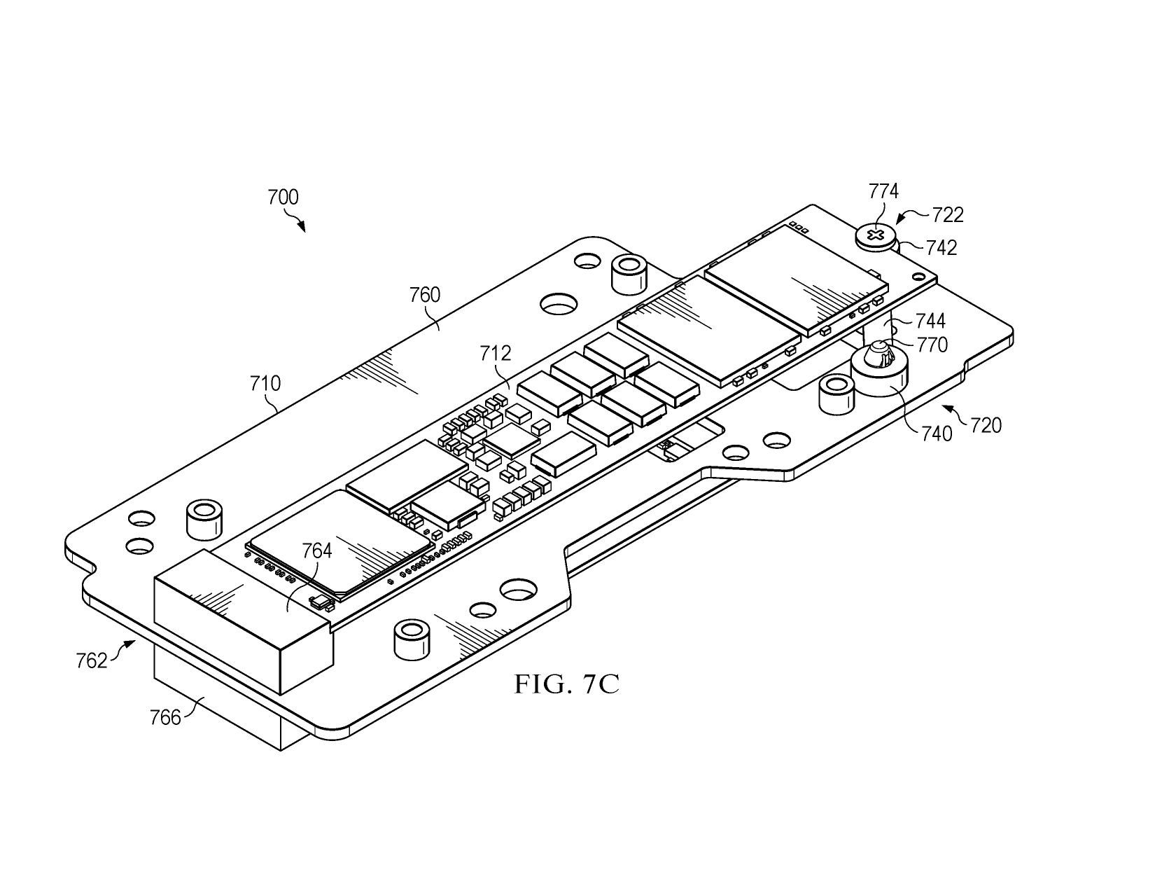

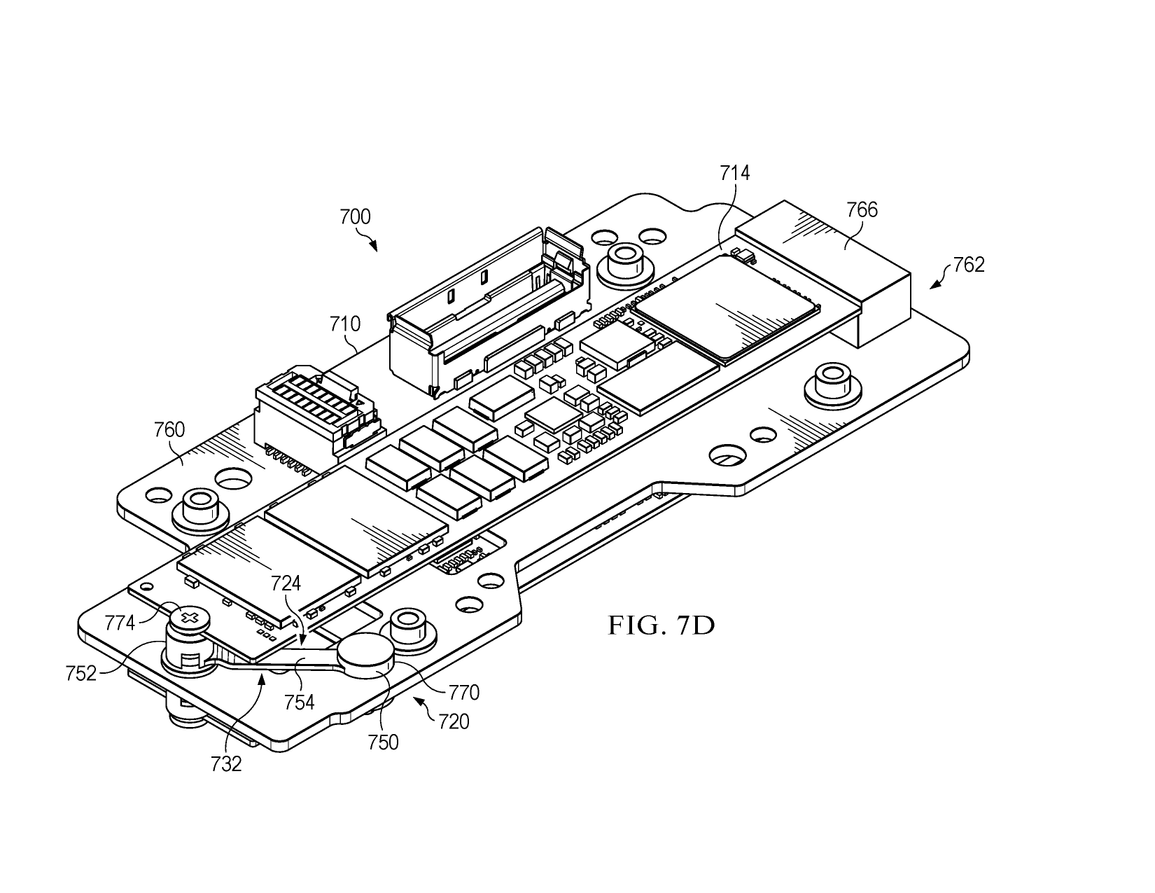

FIGS. 7A, 7B, 7C and 76D, generally referred to as FIG. 7, show a plurality of views of a storage component mounting system having a storage component attachment system. More specifically, FIG. 7A shows a top view of a storage component mounting system 700 having a storage component attachment system 705. FIG. 7B shows a bottom view of a storage component mounting system 700 having a storage component attachment system 705. FIG. 7C shows a top perspective view of a storage component mounting system 700 having a storage component attachment system 705. FIG. 7D shows a bottom perspective view of a storage component mounting system 700 having a storage component attachment system 705. In certain embodiments, the storage component mounting system 700 corresponds to storage component mounting system 600. In certain embodiments, the storage component mounting system 700 is included within a storage module. In certain embodiments, the storage module corresponds to storage module 500.

In certain embodiments, the storage component mounting system 700 includes the storage component attachment system 705, a card mounting device 710, a card 712, a card 714, or a combination thereof. In certain embodiments, the storage component attachment system 705 enables different length storage components to be installed into a storage module of the storage system. In certain embodiments, the storage component attachment system 705 includes a relocatable attachment component. Such a storage component attachment system 705 enables a single card mounting device design to be used for cards of different lengths. In certain embodiments, the storage attachment system supports a plurality of card form factors defined by the M.2 storage device specification (e.g., the M.22280 card form factor and the M.222110 card form factor). In certain embodiments, the card 712, the card 714, or a combination thereof, conform to the M.222110 card form factor.

In certain embodiments, the relocatable attachment component 705 includes a pivot portion 720, a card attachment portion 722, a card attachment extension portion 724, or a combination thereof. In certain embodiment, the card attachment extension portion 724 extends between the pivot portion 720 and the card attachment portion 722. In certain embodiments, the card attachment portion 722 includes a card fastener 726. In certain embodiments, card fastener 726 physically couples the card attachment portion 722 to the card mounting device 710. In certain embodiments, the card fastener 726 physically couples one edge of a card 712, 714 to the card mounting device 710.

In certain embodiments, the relocatable attachment component 705 includes a top side relocatable attachment portion 730, a bottom side relocatable attachment portion 732, or a combination thereof. In certain embodiments, the top side relocatable attachment portion 730 includes a top side pivot portion 740, a top side card attachment portion 742, a top side card attachment extension portion 744, or a combination thereof. In certain embodiment, the top side card attachment extension portion 744 extends between the top side pivot portion 740 and the top side card attachment portion 742. In certain embodiments, the top side card attachment portion 742 includes a top side card fastener 746. In certain embodiments, top side card fastener 746 physically couples the top side card attachment portion 742 to the card mounting device 710. In certain embodiments, the top side card fastener 746 physically couples one edge of a card 712 to a top side of the card mounting device 710. In certain embodiments, the edge of the card 712 is located laterally opposite to top edge card edge connector of the card 712. In certain embodiments, the top side pivot portion 740 defines a top side mounting aperture 748.

In certain embodiments, the bottom side relocatable attachment portion 732 includes a bottom side pivot portion 750, a bottom side card attachment portion 752, a bottom side card attachment extension portion 754, or a combination thereof. In certain embodiment, the bottom side card attachment extension portion 754 extends between the bottom side pivot portion 750 and the bottom side card attachment portion 752. In certain embodiments, the bottom side card attachment portion 752 includes a bottom side card fastener 756. In certain embodiments, bottom side card fastener 756 physically couples the bottom side card attachment portion 752 to the card mounting device 710. In certain embodiments, the bottom side card fastener 756 physically couples one edge of a card 714 to a bottom side of the card mounting device 710. In certain embodiments, the edge of the card 714 is located laterally opposite to the bottom side card edge connector of the card 714. In certain embodiments, the bottom side pivot portion 750 includes a bottom side mounting projection 758. In certain embodiments, the bottom side mounting projection 758 mates with the top side mounting aperture 748 to pivotally attach the top side relocatable attachment portion 730 and the bottom side relocatable attachment portion 732. In certain embodiments, the bottom side mounting projection 758 mates with the top side mounting aperture 748 to pivotally attach the top side relocatable attachment portion 730 and the bottom side relocatable attachment portion 732 such that the top side relocatable attachment portion 730 and the bottom side relocatable attachment portion 732 can pivot independent of each other.

In certain embodiments, the card mounting device 710 includes a mounting card 760, a mounting connector portion 762, or a combination thereof. In certain embodiments, the mounting card includes a mounting card printed circuit board. In certain embodiments, the mounting card includes a top portion, a bottom portion, or a combination thereof. In certain embodiments, the top portion includes a top mounting connector 764. In certain embodiments, the bottom portion includes a bottom mounting connector 766. In certain embodiments, the card 712 is electrically and physically coupled with the top mounting connector 764. In certain embodiments, the card 714 is electrically and physically coupled with the bottom mounting connector 766.

In certain embodiments, the mounting card 760 defines a relocatable attachment component pivot aperture 770, a first relocatable attachment component attachment aperture 772, a second relocatable attachment component attachment aperture 774, or a combination thereof. In certain embodiments, the relocatable attachment component pivot aperture 770 is located close to a side edge of the mounting card 760. In certain embodiments, the relocatable attachment component pivot aperture 770 is located such that the pivot portion of the relocatable attachment component does not interfere with installation of a card 712, 714. In certain embodiments, the bottom side mounting projection 758 fits through the relocatable attachment component pivot aperture 770 to pivotally attach the top side relocatable attachment portion 730 and the bottom side relocatable attachment portion 732.

In certain embodiments, the first relocatable attachment component attachment aperture 772 is located to enable the relocatable attachment component 705 to be configured in a first card attachment configuration. In certain embodiments, the first card attachment configuration enables attachment of a card conforming to a M.22280 card form factor. In certain embodiments, the second relocatable attachment component attachment aperture 774 is located to enable the relocatable attachment component 705 to be configured in a second card attachment configuration. In certain embodiments, the first card attachment configuration enables attachment of a card conforming to a M.222110 card form factor.

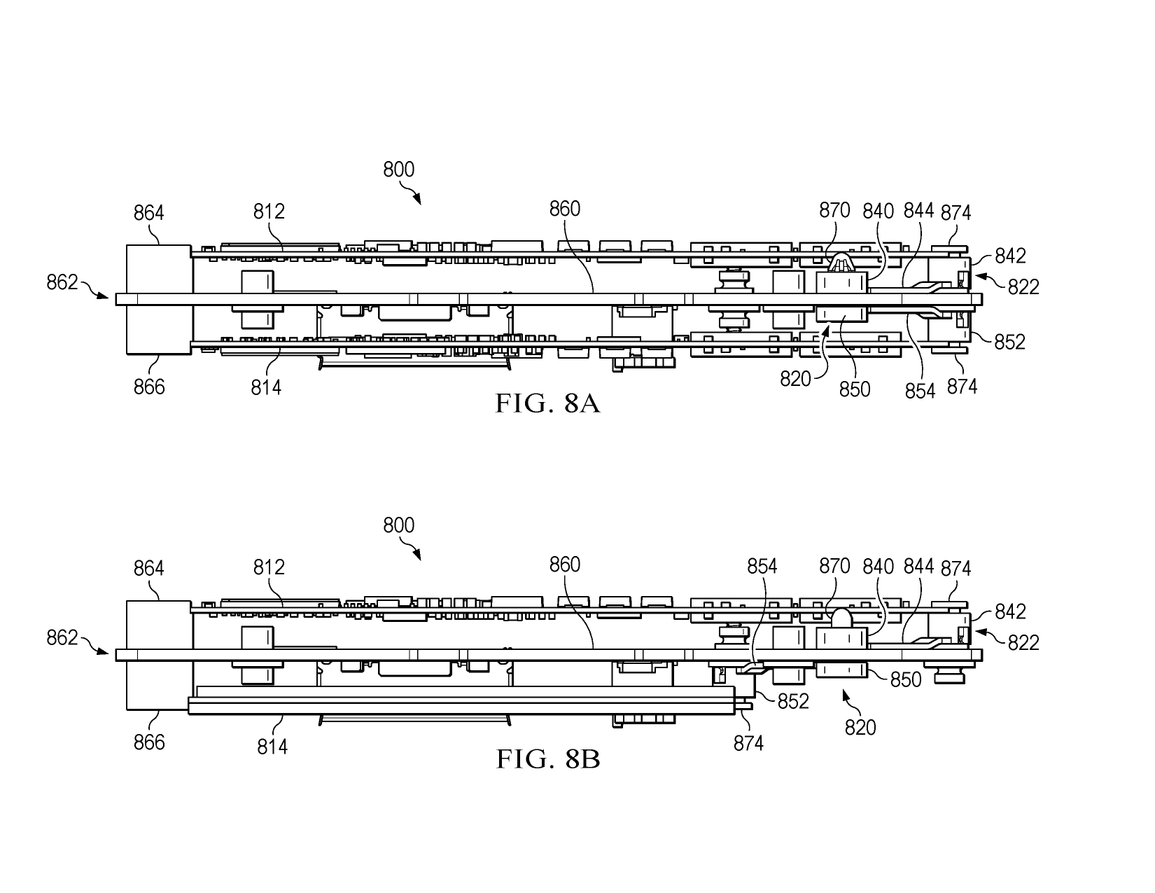

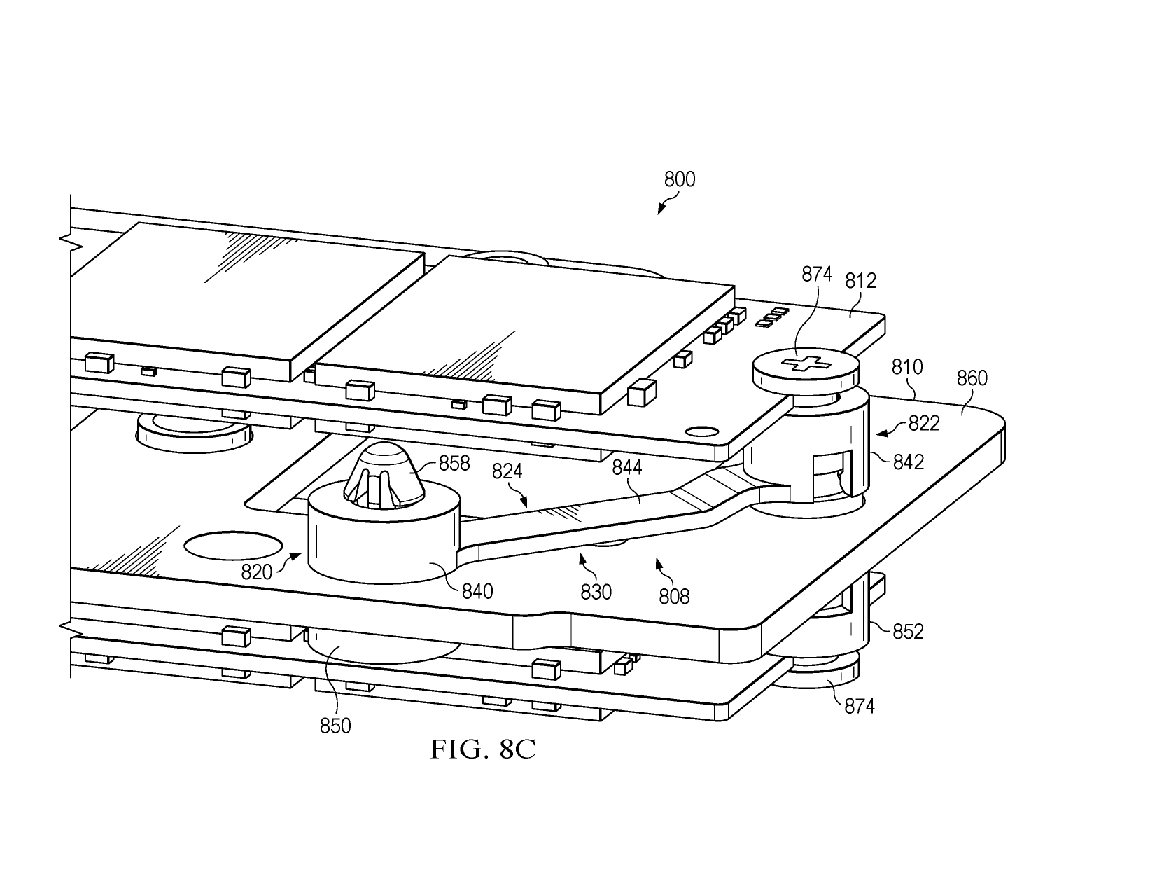

FIGS. 8A, 8B and 8C, generally referred to as FIG. 8, show a plurality of views of a storage component mounting system. More specifically, FIG. 8A shows a side view of a storage component mounting system 800 having a storage component attachment system 805. FIG. 8B shows a side view of a storage component mounting system 800 having a storage component attachment system 805. FIG. 8C shows a top perspective view of a storage component mounting system 800 having a storage component attachment system 805. In certain embodiments, the storage component mounting system 800 corresponds to storage component mounting system 600. In certain embodiments, the storage component mounting system 800 is included within a storage module. In certain embodiments, the storage module corresponds to storage module 500.

In certain embodiments, the storage component mounting system 800 includes the storage component attachment system 805, a card mounting device 810, a card 812, a card 814, or a combination thereof. In certain embodiments, the storage component attachment system 805 enables different length storage components to be installed into a storage module of the storage system. In certain embodiments, the storage component attachment system 805 includes a relocatable attachment component. In certain embodiments, the storage attachment system supports a plurality of card form factors defined by the M.2 storage device specification (e.g., the M.22280 card form factor and the M.222110 card form factor). In certain embodiments, the card 812, the card 714, or a combination thereof, respectively conform to the M.22280 card form factor or the M.222110 card form factor.

In certain embodiments, the card mounting device 810 includes a mounting card 860, a mounting connector portion 862, or a combination thereof. In certain embodiments, the mounting card includes a mounting card printed circuit board. In certain embodiments, the mounting card includes a top portion, a bottom portion, or a combination thereof. In certain embodiments, the top portion includes a top mounting connector 864. In certain embodiments, the bottom portion includes a bottom mounting connector 866. In certain embodiments, the card 812 is electrically and physically coupled with the top mounting connector 864. In certain embodiments, the card 814 is electrically and physically coupled with the bottom mounting connector 866.

In certain embodiments, the mounting card 860 defines a relocatable attachment component pivot aperture 870, a first relocatable attachment component attachment aperture 872, a second relocatable attachment component attachment aperture 874, or a combination thereof. In certain embodiments, the relocatable attachment component pivot aperture 870 is located close to a side edge of the mounting card 860. In certain embodiments, the relocatable attachment component pivot aperture 870 is located such that the pivot portion of the relocatable attachment component does not interfere with installation of a card 812, 814. In certain embodiments, the bottom side mounting projection 858 fits through the relocatable attachment component pivot aperture 870 to pivotally attach the top side relocatable attachment portion 830 and the bottom side relocatable attachment portion 832.

In certain embodiments, the first relocatable attachment component attachment aperture 872 is located to enable the relocatable attachment component 805 to be configured in a first card attachment configuration. In certain embodiments, the first card attachment configuration enables attachment of a card conforming to a M.22280 card form factor. In certain embodiments, the second relocatable attachment component attachment aperture 874 is located to enable the relocatable attachment component 805 to be configured in a second card attachment configuration. In certain embodiments, the first card attachment configuration enables attachment of a card conforming to a M.222110 card form factor.

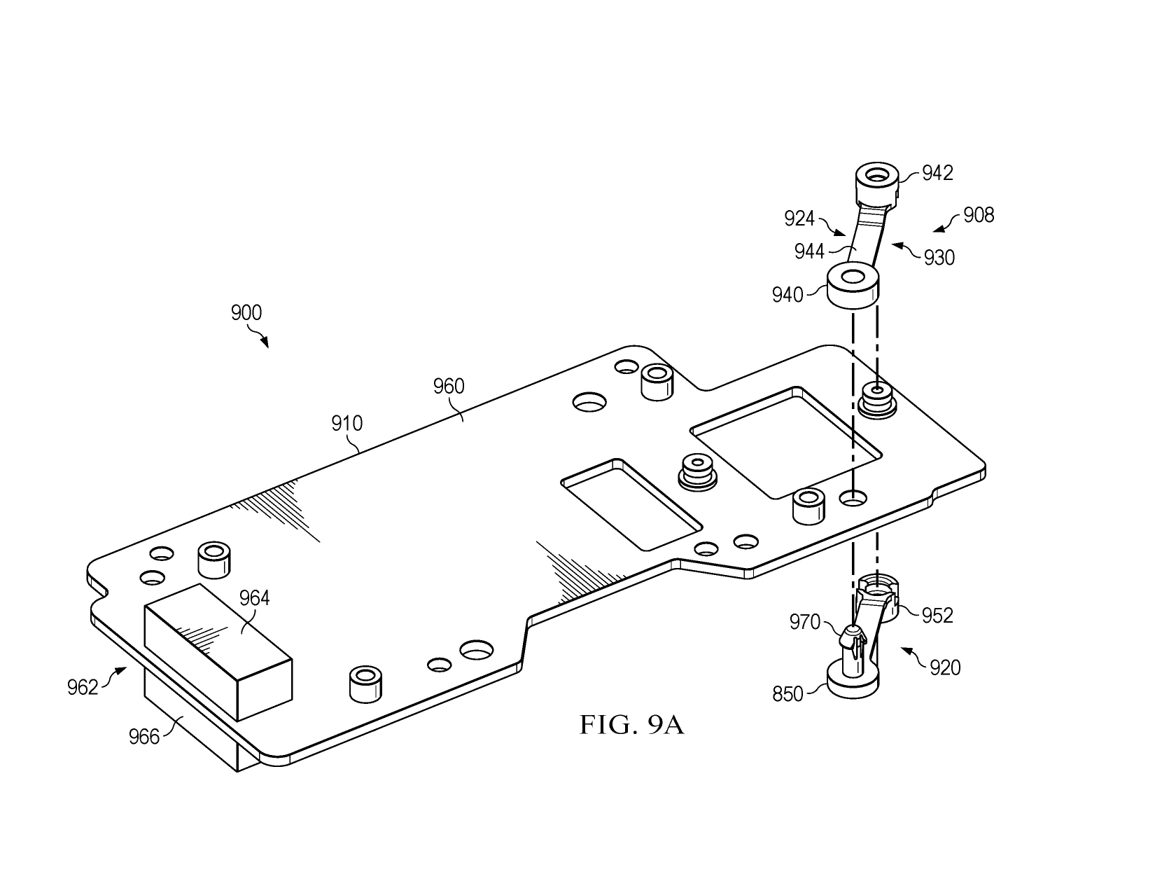

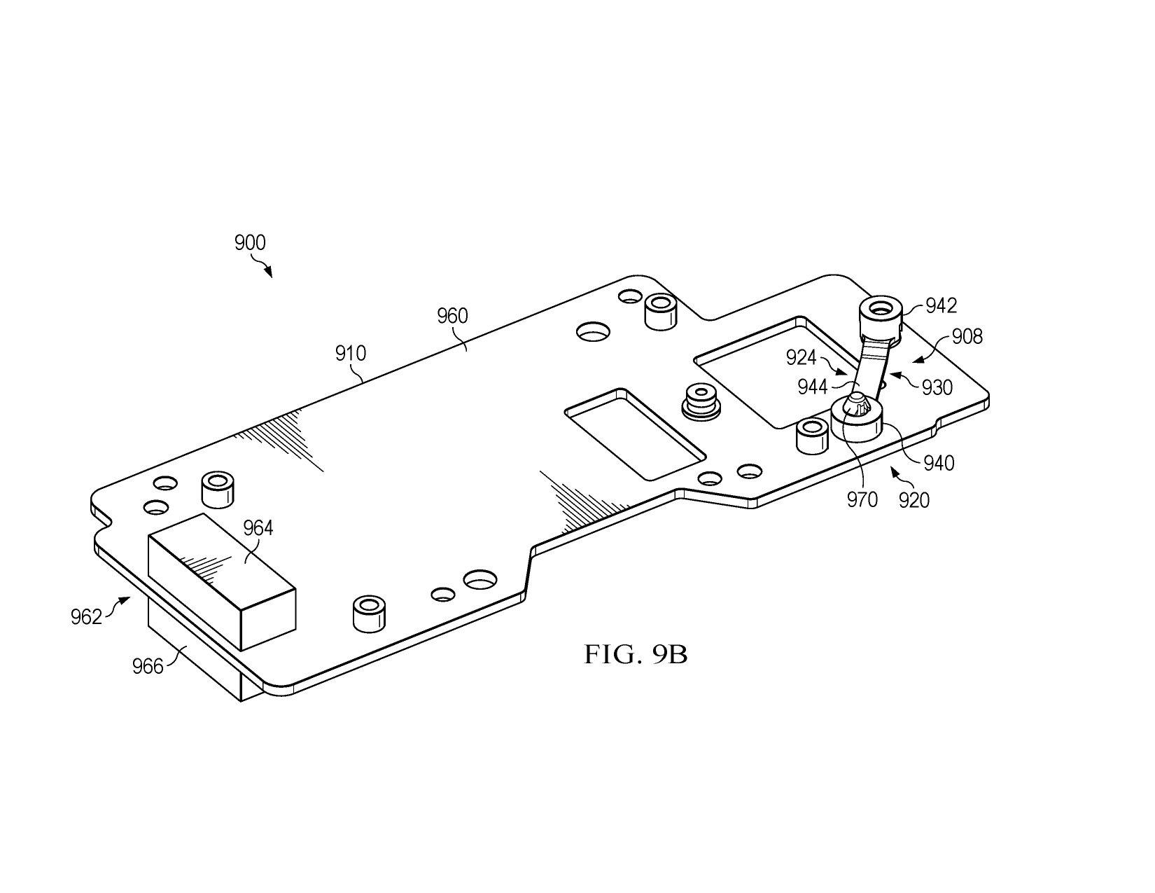

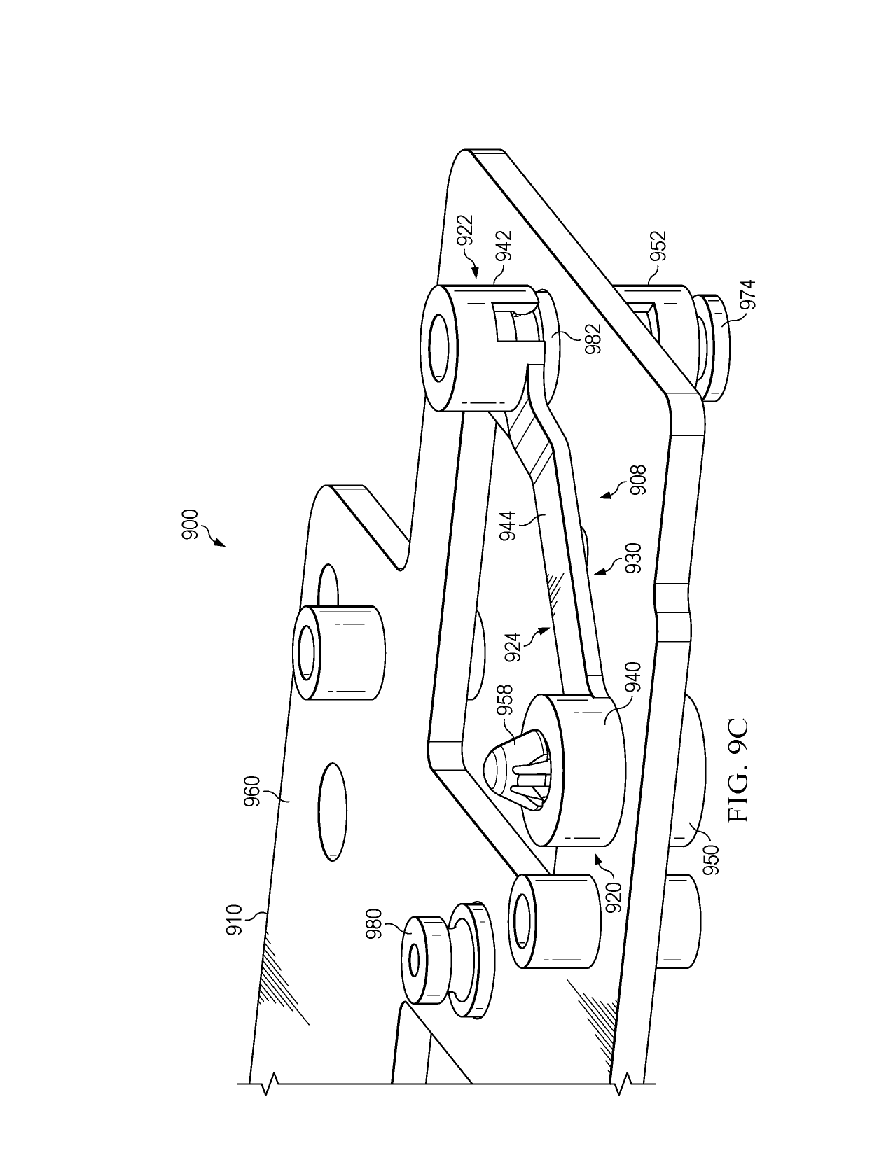

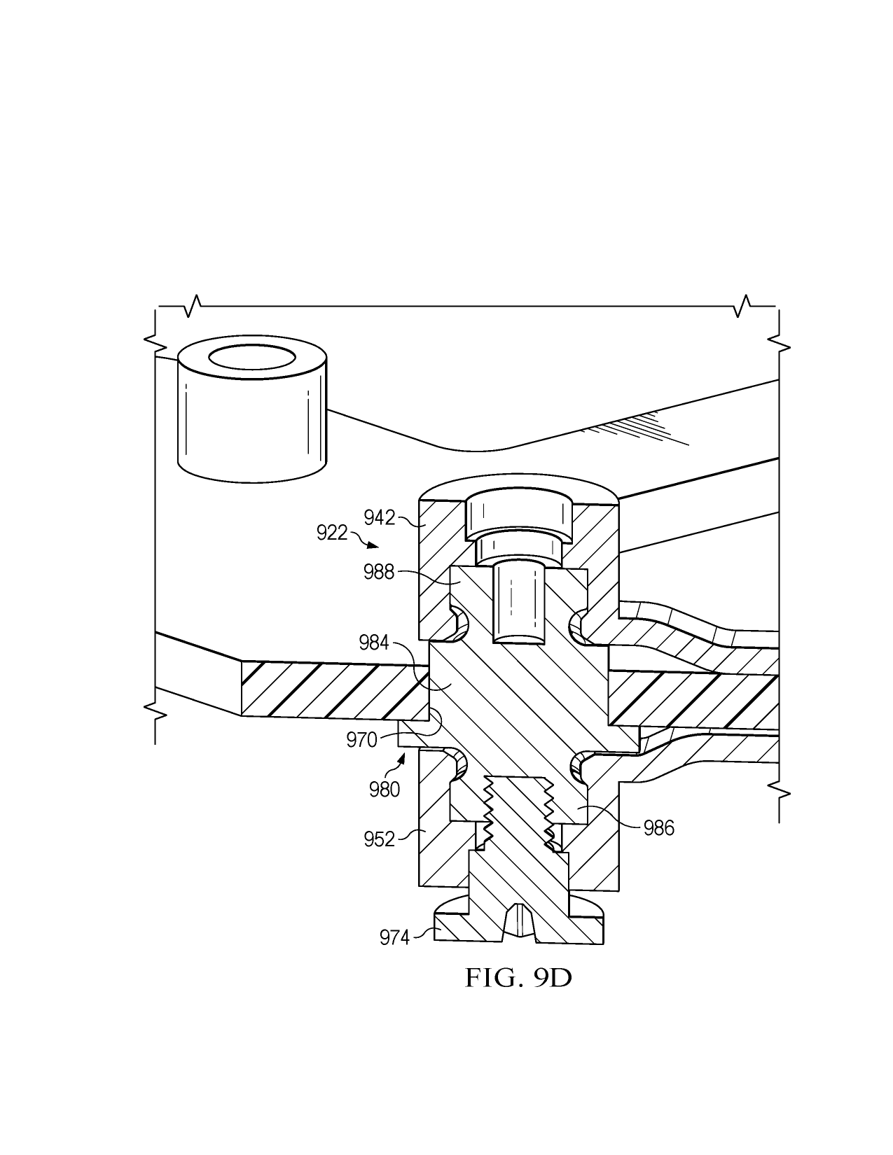

FIGS. 9A, 9B, 9C and 9D, generally referred to as FIG. 9, show a plurality of views of a storage component mounting system having a storage component attachment system. More specifically, FIG. 9A shows an exploded perspective top view of a storage component mounting system 900 having a storage component attachment system 905. FIG. 9B shows a perspective top view of a storage component mounting system 900 having a storage component attachment system 905. FIG. 9C shows a top perspective view of a storage component mounting system 900 having a storage component attachment system 905. FIG. 9D shows a cut away side view of a storage component mounting system 900 having a storage component attachment system 905. In certain embodiments, the storage component mounting system 900 corresponds to storage component mounting system 600. In certain embodiments, the storage component mounting system 900 is included within a storage module. In certain embodiments, the storage module corresponds to storage module 500.

In certain embodiments, the storage component mounting system 900 includes the storage component attachment system 905, a card mounting device 910, or a combination thereof. In certain embodiments, the storage component attachment system 905 enables different length storage components to be installed into a storage module of the storage system. In certain embodiments, the storage component attachment system 905 includes a relocatable attachment component. Such a storage component attachment system 905 enables a single card mounting device design to be used for cards of different lengths. In certain embodiments, the storage attachment system supports a plurality of card form factors defined by the M.2 storage device specification (e.g., the M.22280 card form factor and the M.222110 card form factor). In certain embodiments, the card 912, the card 914, or a combination thereof, conform to the M.22280 card form factor.

In certain embodiments, the relocatable attachment component 905 includes a pivot portion 920, a card attachment portion 922, a card attachment extension portion 924, or a combination thereof. In certain embodiment, the card attachment extension portion 924 extends between the pivot portion 920 and the card attachment portion 922. In certain embodiments, the card attachment portion 922 includes a card fastener 926. In certain embodiments, card fastener 926 physically couples the card attachment portion 922 to the card mounting device 910. In certain embodiments, the card fastener 926 physically couples one edge of a card 912, 914 to the card mounting device 910.

In certain embodiments, the relocatable attachment component 905 includes a top side relocatable attachment portion 930, a bottom side relocatable attachment portion 932, or a combination thereof. In certain embodiments, the top side relocatable attachment portion 930 includes a top side pivot portion 940, a top side card attachment portion 942, a top side card attachment extension portion 944, or a combination thereof. In certain embodiment, the top side card attachment extension portion 944 extends between the top side pivot portion 940 and the top side card attachment portion 942. In certain embodiments, the top side card attachment portion 942 includes a top side card fastener 946. In certain embodiments, top side card fastener 946 physically couples the top side card attachment portion 942 to the card mounting device 910. In certain embodiments, the top side card fastener 946 physically couples one edge of a card 912 to a top side of the card mounting device 910. In certain embodiments, the edge of the card 912 is located laterally opposite to top edge card edge connector of the card 912. In certain embodiments, the top side pivot portion 940 defines a top side mounting aperture 948.

In certain embodiments, the bottom side relocatable attachment portion 932 includes a bottom side pivot portion 950, a bottom side card attachment portion 952, a bottom side card attachment extension portion 954, or a combination thereof. In certain embodiment, the bottom side card attachment extension portion 954 extends between the bottom side pivot portion 950 and the bottom side card attachment portion 952. In certain embodiments, the bottom side card attachment portion 952 includes a bottom side card fastener 956. In certain embodiments, bottom side card fastener 956 physically couples the bottom side card attachment portion 952 to the card mounting device 910. In certain embodiments, the bottom side card fastener 956 physically couples one edge of a card 914 to a bottom side of the card mounting device 910. In certain embodiments, the edge of the card 914 is located laterally opposite to the bottom side card edge connector of the card 914. In certain embodiments, the bottom side pivot portion 950 includes a bottom side mounting projection 958. In certain embodiments, the bottom side mounting projection 958 mates with the top side mounting aperture 948 to pivotally attach the top side relocatable attachment portion 930 and the bottom side relocatable attachment portion 932. In certain embodiments, the bottom side mounting projection 958 mates with the top side mounting aperture 948 to pivotally attach the top side relocatable attachment portion 930 and the bottom side relocatable attachment portion 932 such that the top side relocatable attachment portion 930 and the bottom side relocatable attachment portion 932 can pivot independent of each other.

In certain embodiments, the card mounting device 910 includes a mounting card 960, a mounting connector portion 962, or a combination thereof. In certain embodiments, the mounting card includes a mounting card printed circuit board. In certain embodiments, the mounting card includes a top portion, a bottom portion, or a combination thereof. In certain embodiments, the top portion includes a top mounting connector 964. In certain embodiments, the bottom portion includes a bottom mounting connector 966. In certain embodiments, the card 912 is electrically and physically coupled with the top mounting connector 964. In certain embodiments, the card 914 is electrically and physically coupled with the bottom mounting connector 966.

In certain embodiments, the mounting card 960 defines a relocatable attachment component pivot aperture 970, a first relocatable attachment component attachment aperture 972, a second relocatable attachment component attachment aperture 974, or a combination thereof. In certain embodiments, the relocatable attachment component pivot aperture 970 is located close to a side edge of the mounting card 960. In certain embodiments, the relocatable attachment component pivot aperture 970 is located such that the pivot portion of the relocatable attachment component does not interfere with installation of a card 912, 914. In certain embodiments, the bottom side mounting projection 958 fits through the relocatable attachment component pivot aperture 970 to pivotally attach the top side relocatable attachment portion 930 and the bottom side relocatable attachment portion 932.

In certain embodiments, the first relocatable attachment component attachment aperture 972 is located to enable the relocatable attachment component 905 to be configured in a first card attachment configuration. In certain embodiments, the first card attachment configuration enables attachment of a card conforming to a M.22280 card form factor. In certain embodiments, the second relocatable attachment component attachment aperture 974 is located to enable the relocatable attachment component 905 to be configured in a second card attachment configuration. In certain embodiments, the first card attachment configuration enables attachment of a card conforming to a M.222110 card form factor.

In certain embodiments, the card mounting device 910 includes a first relocatable attachment component attachment device 980, a second relocatable attachment component attachment device 982, or a combination thereof. In certain embodiments, the first relocatable attachment component attachment device 980 fits within the first relocatable attachment component attachment aperture 972. In certain embodiments, the second relocatable attachment component attachment device 982 fits within the second relocatable attachment component attachment aperture 974. In certain embodiments, each of the first relocatable attachment component attachment devices 980, 982 include an aperture housing portion 984, a top attachment recess 986, a bottom attachment recess 988, or a combination thereof. In certain embodiments, the aperture housing portion 984 is located between the top attachment recess 986 and the bottom attachment recess 988. In certain embodiments a top fastener component 990 is used to physically attach the top side attachment portion 942 to a respective relocatable component attachment device 980, 982. In certain embodiments a bottom fastener component 992 is used to physically attach the bottom side attachment portion 952 to a respective relocatable component attachment device 980, 982. In certain embodiments, one or both of the top fastener component 990 and the bottom fastener component 992 can include respective screw components.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A storage component attachment system for attaching a storage component within a storage system for an information handling system, comprising:
a card attachment portion, the card attachment portion including a card fastener, the card fastener physically coupling the storage component to a card mounting device;
a pivot portion, the pivot portion enabling the card attachment portion to pivot between a plurality of locations on the card mounting device to enable storage components corresponding to a plurality of storage component form factors to be mounted to a single card mounting device design; and,
a card attachment extension portion, the card attachment extension portion extending between the card attachment portion and the pivot portion.

2. The storage component attachment system of claim 1, wherein:
the storage component attachment system comprises a top side relocatable attachment portion, the top side relocatable attachment portion comprising the card attachment portion, the pivot portion and the card attachment extension portion.

3. The storage component attachment system of claim 2, wherein:
the storage component attachment system comprises a bottom side relocatable attachment portion, the bottom side relocatable attachment portion comprising a bottom side card attachment portion, a bottom side pivot portion and a bottom side card attachment extension portion.

4. The storage component attachment system of claim 3, wherein:
the top side relocatable attachment portion and the bottom side relocatable attachment portion are physically coupled via the pivot portion and the bottom side pivot portion.

5. The storage component attachment system of claim 4, wherein:
the top side relocatable attachment portion and the bottom side relocatable attachment portion are configured to pivot independently of each other.

6. The storage component attachment system of claim 1, wherein:
the plurality of storage component form factors are defined by an M.2 storage device specification; and,
the plurality of card form factors include an M.2 2280 card form factor and an M.2 22110 card form factor.

7. A storage component mounting system of a storage system comprising:
a card mounting device; and,
a storage component attachment system, the storage component attachment system comprising
a card attachment portion, the card attachment portion including a card fastener, the card fastener physically coupling the storage component to the card mounting device;
a pivot portion, the pivot portion enabling the card attachment portion to pivot between a plurality of locations on the card mounting device to enable storage components corresponding to a plurality of storage component form factors to be mounted to a single card mounting device design; and,
a card attachment extension portion, the card attachment extension portion extending between the card attachment portion and the pivot portion.

8. The bottom system of claim 7, wherein:
the storage component attachment system comprises a top side relocatable attachment portion, the top side relocatable attachment portion comprising the card attachment portion, the pivot portion and the card attachment extension portion.

9. The bottom system of claim 8, wherein:
the storage component attachment system comprises a bottom side relocatable attachment portion, the bottom side relocatable attachment portion comprising a bottom side card attachment portion, a bottom side pivot portion and a bottom side card attachment extension portion.

10. The bottom system of claim 9, wherein:
the top side relocatable attachment portion and the bottom side relocatable attachment portion are physically coupled via the pivot portion and the bottom side pivot portion.

11. The bottom system of claim 10, wherein:
the top side relocatable attachment portion and the bottom side relocatable attachment portion are configured to pivot independently of each other.

12. The bottom system of claim 7, wherein:
the plurality of storage component form factors are defined by an M.2 storage device specification; and,
the plurality of card form factors include an M.2 2280 card form factor and an M.2 22110 card form factor.

13. A system comprising:
a chassis;
a processor contained within the chassis;
a data bus coupled to the processor; and,
a storage system comprising a storage component mounting system, the storage component mounting system comprising
a card mounting device; and,
a storage component attachment system, the storage component attachment system comprising
a card attachment portion, the card attachment portion including a card fastener, the card fastener physically coupling the storage component to the card mounting device;
a pivot portion, the pivot portion enabling the card attachment portion to pivot between a plurality of locations on the card mounting device to enable storage components corresponding to a plurality of storage component form factors to be mounted to a single card mounting device design; and,
a card attachment extension portion, the card attachment extension portion extending between the card attachment portion and the pivot portion.

14. The system of claim 13, wherein:
the storage component attachment system comprises a top side relocatable attachment portion, the top side relocatable attachment portion comprising the card attachment portion, the pivot portion and the card attachment extension portion.

15. The system of claim 14, wherein:
the storage component attachment system comprises a bottom side relocatable attachment portion, the bottom side relocatable attachment portion comprising a bottom side card attachment portion, a bottom side pivot portion and a bottom side card attachment extension portion.

16. The system of claim 15, wherein:
the top side relocatable attachment portion and the bottom side relocatable attachment portion are physically coupled via the pivot portion and the bottom side pivot portion.

17. The system of claim 16, wherein:
the top side relocatable attachment portion and the bottom side relocatable attachment portion are configured to pivot independently of each other.

18. The system of claim 15, wherein:
the plurality of storage component form factors are defined by an M.2 storage device specification; and,
the plurality of card form factors include an M.2 2280 card form factor and an M.2 22110 card form factor.
